(19) United States
(12) Patent Application Publication
(10) Pub. No.: US 2025/0107219 A1
(43) Pub. Date: Mar. 27, 2025

(54) SPACER MODIFICATION FOR SELECTIVE AIRGAP SPACER FORMATION

(71) Applicant: INTERNATIONAL BUSINESS MACHINES CORPORATION, ARMONK, NY (US)

(72) Inventors: Juntao Li, Cohoes, NY (US); Ruilong Xie, Niskayuna, NY (US); Tao Li, Slingerlands, NY (US); Kisik Choi, Watervliet, NY (US); Nicolas Jean Loubet, GUILDERLAND, NY (US)

(21) Appl. No.: 18/472,470

(22) Filed: Sep. 22, 2023

(51) Int. Cl. H01L 27/088; H01L 29/06; H01L 29/417; H01L 29/423; H01L 29/775; H01L 29/786

(52) U.S. Cl. CPC H10D 84/83; H10D 30/43; H10D 30/6735; H10D 30/6757; H10D 62/121; H10D 64/258

(57) ABSTRACT

A microelectronic structure includes a first nanosheet transistor column. The first nanosheet transistor column includes a plurality of first channel layers and a first gate located around each of the plurality of first channel layers. A second nanosheet transistor column that includes a plurality of second channel layers and a second gate located around each of the plurality of second channel layers. The first nanosheet transistor column is adjacent to the second nanosheet column. A source/drain located between the first nanosheet transistor column and the second nanosheet transistor column. A dielectric cap located on top of and in direct contact with a frontside surface of the source/drain. The dielectric cap is in contact with a sidewall of the first gate and the dielectric cap is in contact with a sidewall of the second gate.

### BACKGROUND

The present invention generally relates to the field of microelectronics, and more particularly to formation of an airgap in a nanosheet transistor.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form the necessary isolation between adjacent devices.

### BRIEF SUMMARY

Additional aspects and/or advantages will be set forth in part in the description which follows and, in part, will be apparent from the description, or may be learned by practice of the invention.

A microelectronic structure includes a first nanosheet transistor column. The first nanosheet transistor column includes a plurality of first channel layers and a first gate located around each of the plurality of first channel layers. A second nanosheet transistor column that includes a plurality of second channel layers and a second gate located around each of the plurality of second channel layers. The first nanosheet transistor column is adjacent to the second nanosheet column. A source/drain located between the first nanosheet transistor column and the second nanosheet transistor column. A dielectric cap located on top of and in direct contact with a frontside surface of the source/drain. The dielectric cap is in contact with a sidewall of the first gate and the dielectric cap is in contact with a sidewall of the second gate.

A microelectronic structure includes a first nanosheet transistor column. The first nanosheet transistor column includes a plurality of first channel layers and a first gate located around each of the plurality of first channel layers. A second nanosheet transistor column that includes a plurality of second channel layers and a second gate located around each of the plurality of second channel layers. The first nanosheet transistor column is adjacent to the second nanosheet column NSC2. A first source/drain located between the first nanosheet transistor column and the second nanosheet transistor column. A dielectric cap located on top of and in direct contact with a frontside surface of the first source/drain. The dielectric cap is in contact with a sidewall of the first gate and the dielectric cap is in contact with a sidewall of the second gate. An airgap located adjacent to the second gate. The airgap is located on the opposite side of the second gate than the dielectric cap. The airgap is vertically aligned over the plurality of second channel layers.

A microelectronic structure including a plurality of nanosheet transistor columns and the plurality of nanosheet columns are horizontally aligned. A first dielectric cap located between and in contact with a gate of two adjacent nanosheet transistor columns and the first dielectric cap is horizontally aligned with the plurality of nanosheet columns. A second dielectric cap located in a region adjacent to the plurality of nanosheet transistor columns and the second dielectric cap is located and in contact with two adjacent gates.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a nanosheet transistors, in accordance with the embodiment of the present invention.

FIG. 2 illustrates a cross section X1 of the nanosheet transistor after the initial processing of the nanosheet transistor, in accordance with the embodiment of the present invention.

FIG. 3 illustrates a cross section X2 of the nanosheet transistor after the initial processing of the nanosheet transistor, in accordance with the embodiment of the present invention.

FIG. 4 illustrates a cross section X1 of the nanosheet transistor after formation and patterning of a first lithography layer, in accordance with the embodiment of the present invention.

FIG. 5 illustrates a cross section X2 of the nanosheet transistor after formation and patterning of a first lithography layer, in accordance with the embodiment of the present invention.

FIG. 6 illustrates a cross section X1 of the nanosheet transistor after formation of extended trenches, in accordance with the embodiment of the present invention.

FIG. 7 illustrates a cross section X2 of the nanosheet transistor after formation of extended trenches, in accordance with the embodiment of the present invention.

FIG. 8 illustrates a cross section X1 of the nanosheet transistor after removal of the first lithography layer and the formation of the placeholder and a new source/drain, in accordance with the embodiment of the present invention.

FIG. 9 illustrates a cross section X1 of the nanosheet transistor after gate spacer pull down, formation of a first dielectric cap and a second dielectric cap, and the removal of the hardmask, in accordance with the embodiment of the present invention.

FIG. 10 illustrates a cross section X2 of the nanosheet transistor after gate spacer pull down, formation of a first dielectric cap and a second dielectric cap, and the removal of the hardmask, in accordance with the embodiment of the present invention.

FIG. 11 illustrates a cross section X1 of the nanosheet transistor after removal of the dummy gate and the sacrificial layers and the formation of the gate, in accordance with the embodiment of the present invention.

FIG. 12 illustrates a cross section X2 of the nanosheet transistor after removal of the dummy gate and the sacrificial layers and the formation of the gate, in accordance with the embodiment of the present invention.

FIG. 13 illustrates a cross section X1 of the nanosheet transistor after formation of frontside source/drain contacts, in accordance with the embodiment of the present invention.

FIG. 14 illustrates a cross section X1 of the nanosheet transistor after pulling down the gate spacer to create a plurality of trenches/valleys, in accordance with the embodiment of the present invention.

FIG. 15 illustrates a cross section X2 of the nanosheet transistor after pulling down the gate spacer to create a plurality of trenches/valleys, in accordance with the embodiment of the present invention.

FIG. 16 illustrates a cross section X1 of the nanosheet transistor after non-conformal formation of a dielectric layer, in accordance with the embodiment of the present invention.

FIG. 17 illustrates a cross section X2 of the nanosheet transistor after non-conformal formation of a dielectric layer, in accordance with the embodiment of the present invention.

FIG. 18 illustrates a cross section X1 of the nanosheet transistor after formation of gate contacts, formation of connecting vias, formation for a second dielectric layer, formation of M1 metal lines, formation of back-end-of-the-lines (BEOL) layers, and formation of a carrier wafer, in accordance with the embodiment of the present invention.

FIG. 19 illustrates a cross section X2 of the nanosheet transistor after formation of gate contacts, formation of connecting vias, formation for a second dielectric layer, formation of M1 metal lines, formation of back-end-of-the-lines (BEOL) layers, and formation of a carrier wafer, in accordance with the embodiment of the present invention.

FIG. 20 illustrates a cross section X1 of the nanosheet transistor after being flipped over for backside processing and the removal of the first substrate, the etch stop, the second substrate, and formation of a carrier wafer, in accordance with the embodiment of the present invention.

FIG. 21 illustrates a cross section X2 of the nanosheet transistor after being flipped over for backside processing and the removal of the first substrate, the etch stop, the second substrate, and formation of a carrier wafer, in accordance with the embodiment of the present invention.

FIG. 22 illustrates a cross section X1 of the nanosheet transistor after formation of backside interlayer dielectric layer, in accordance with the embodiment of the present invention.

FIG. 23 illustrates a cross section X1 of the nanosheet transistor after removal of the placeholder, and the formation of the backside contact and the backside-power-distribution-network, in accordance with the embodiment of the present invention.

FIG. 24 illustrates a cross section X2 of the nanosheet transistor after removal of the placeholder, and the formation of the backside contact and the backside-power-distribution-network, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards the formation of an airgap, where the airgap is located adjacent to the gate. The airgaps are being utilized as substitutes for the gate spacer. After the formation of the gate and the necessary frontside source/drain contacts, then the gate spacer is pulled down. The pulling down of the gate spacer causes the creation of narrow valleys/trenches located adjacent to the gates. A non-conformal or conformal process (as long as it is not a liquid fill operation) for the formation of a dielectric layer will lead to the pinching off of the entrance of the narrow valleys/trenches leading to the creation of airgaps adjacent to the gates.

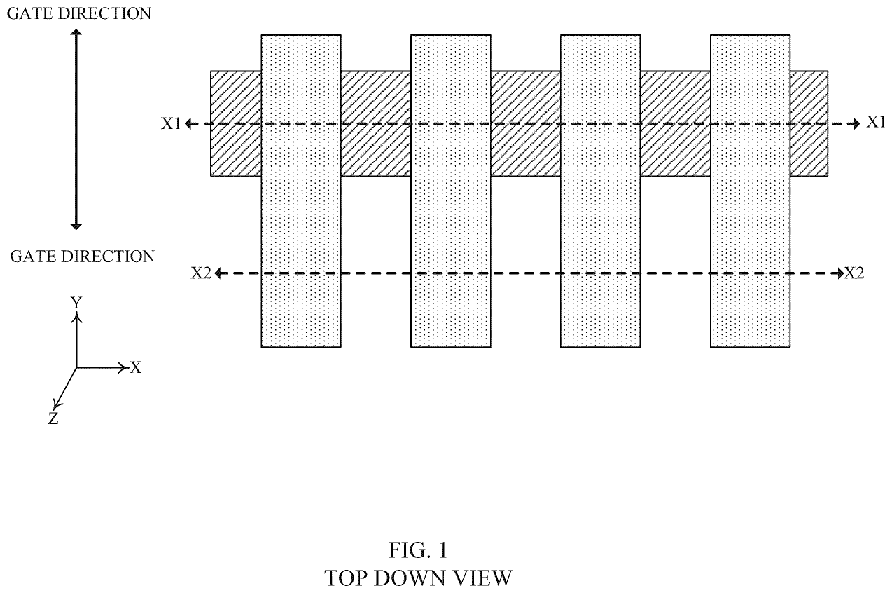

FIG. 1 illustrates a top-down view of multiple devices (nanosheet transistors), in accordance with the embodiment of the present invention. The cross-section X1 extends horizontally through nanosheet transistors. The cross-section X2 extends horizontally through the region adjacent to the nanosheet transistors. Cross-sections X1 and X2 are perpendicular to the gate direction.

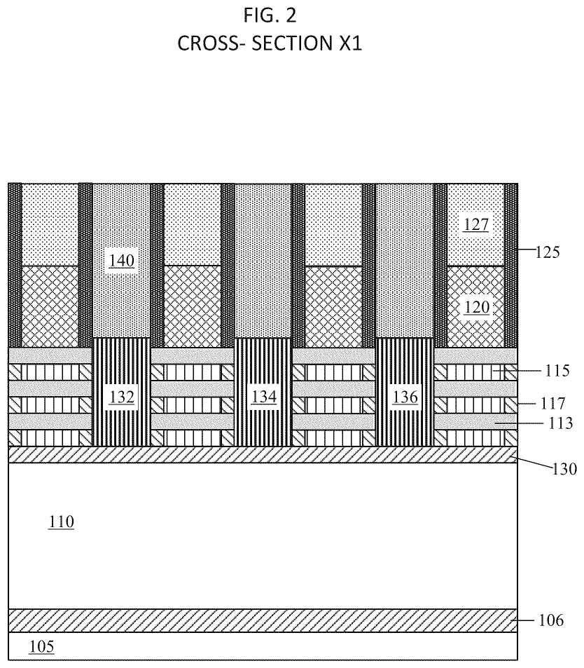

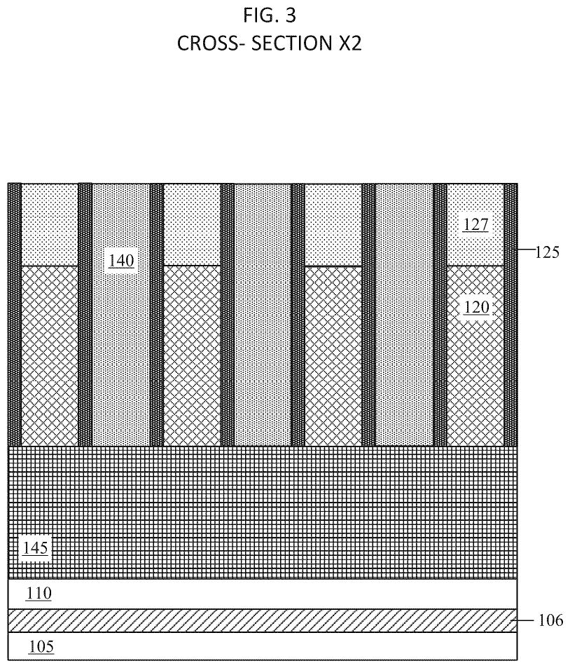

Referring now to FIGS. 2, and 3, a structure is shown during an intermediate step of a method of fabricating stacked nano devices, such as, a stacked nanosheet transistor structure after the initial processing of the nanosheet transistor, according to an embodiment of the invention.

FIGS. 2, and 3 illustrate the processing stage after the initial processing of the nanosheet transistor.

FIG. 2 illustrates the nanosheet transistor that includes a first substrate 105, an etch stop 106, a second substrate 110, a bottom dielectric isolation layer 130, a plurality of nanosheet columns. The nanosheet columns are comprised of a plurality of channel layers 113, a plurality of sacrificial layers 115, an inner spacer 117, a gate spacer 125, a dummy gate 120, and a hardmask 127. The plurality of channel layers 113 can be comprised of, for example, Si. The plurality of sacrificial layers 115 can be comprised of SiGe, where Ge is in the percentage of 15 to 35%.

The first substrate 105 and the second substrate 110 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the first substrate 105 and the second substrate 110. In some embodiments, first substrate 105 and the second substrate 110 includes both semiconductor materials and dielectric materials. The semiconductor first substrate 105 and the second substrate 110 may also comprise an organic semiconductor or a layered semiconductor such as, for example, Si/SiGe, a silicon-on-insulator or a SiGe-on-insulator. A portion or the entire semiconductor first substrate 105 and the second substrate 110 may also be comprised of an amorphous, polycrystalline, or monocrystalline. The semiconductor first substrate 105 and the second substrate 110 may be doped, undoped or contain doped regions and undoped regions therein.

A source/drain 132, 134, 136 is located between each of the nanosheet columns, respectively. A frontside interlayer dielectric layer 140 is located on top of each of the source/drains 132, 134, 136. The source/drains 132, 134, 136, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (TI) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

FIG. 3 illustrates a cross-section X2 through the region adjacent to the nanosheet transistors. Cross-section X2 illustrates a cut horizontally through a plurality of gate regions that are formed on top of the shallow trench isolation layer 145. Each of the gate region includes the dummy gate 120, gate spacers 125, and hardmask 127. The frontside interlayer dielectric layer 140 is located between each of the gate regions.

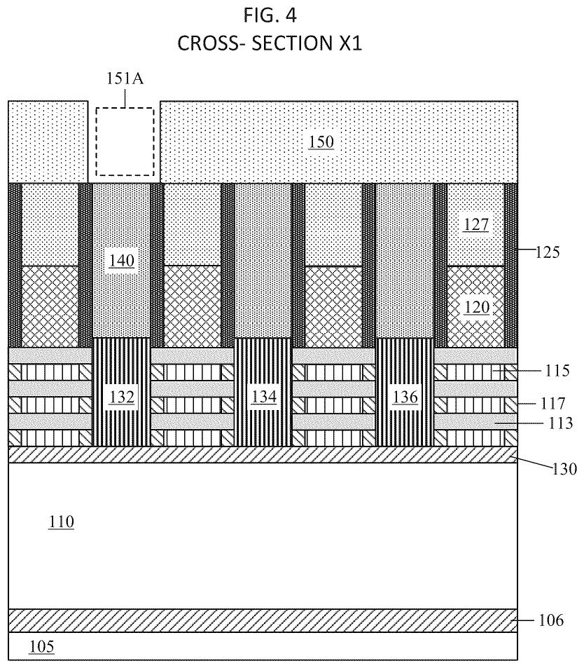

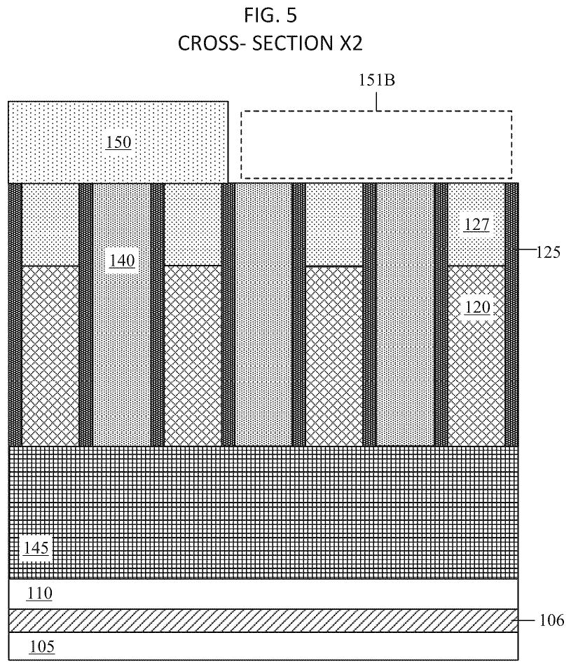

FIGS. 4 and 5 illustrate the processing stage after formation and patterning of a first lithography layer 150. The first lithography layer 150 is formed on top of gate spacer 125, the hardmask 127, and on top of the frontside interlayer dielectric layer 140. The first lithography layer 150 is patterned to create a plurality of trenches 151A, 151B located in the first lithography layer 150. The first trench 151A is located above the frontside interlayer dielectric layer 140, such that the first trench 151A is located above the source/drain region, or it locate between two adjacent gate regions. The second trench 151B is positioned in the space adjacent to the nanosheet transistor, such that, the second trench 151B extends across a plurality of gate regions. The illustrated and described locations of the first and second trench 151A, and 151B are meant for exemplary purposes only, and can be located at different locations.

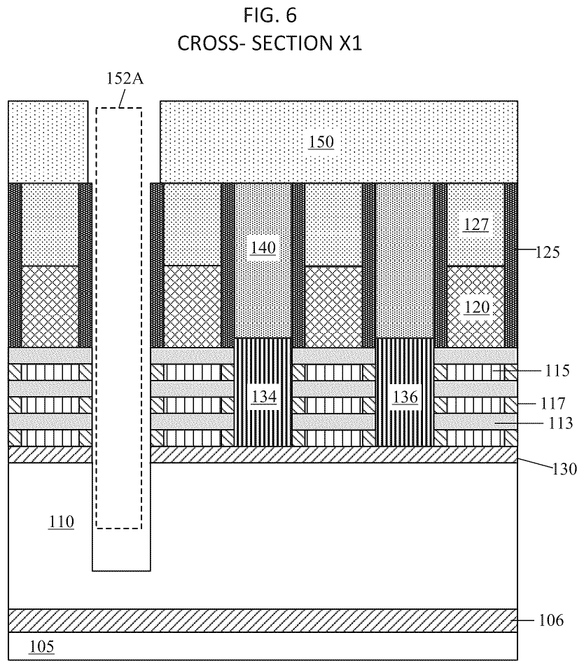

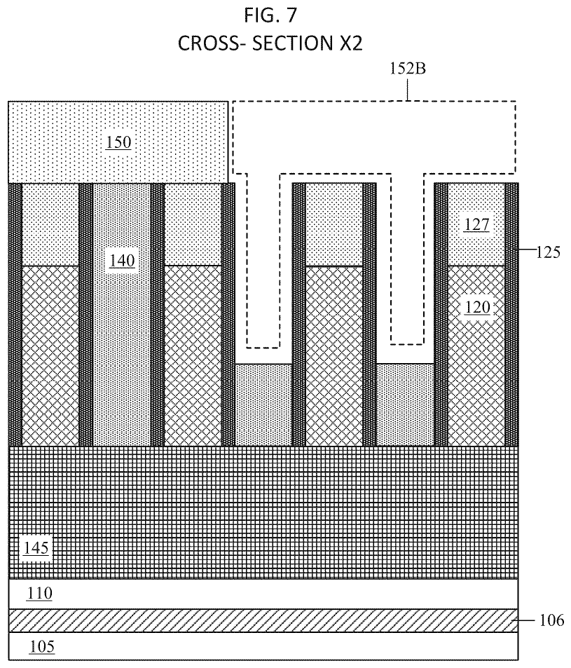

FIGS. 6 and 7 illustrate the processing stage after formation of extended trenches 152A, 152B. The extended first trench 152A is formed by extending the first trench 151A downwards through source/drain 132 into the second substrate 110, as illustrated in FIG. 6. The first extended trench 152A is located in the source/drain region between two adjacent nanosheet columns. The extended second trench 152B is formed by extending the second trench 151B downwards through the frontside interlayer dielectric layer 140. The extended second trench 152B extends horizontally/laterally on top of multiple gate regions and the extended second trench 152B can include one or more downward branches, where each of the downward branches extends downwards between two adjacent gate regions.

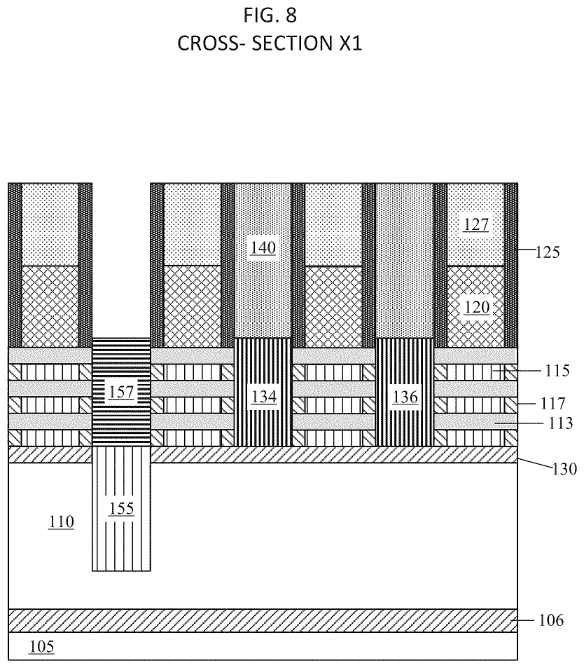

FIG. 8 illustrates the processing stage after removal of the first lithography layer 150 and the formation of the placeholder 155 and a new source/drain 157. The first lithography layer 150 is removed and a placeholder 155 is formed in the bottom of the extended first trench 152A. A new source/drain 157 is formed on top of the placeholder 155, where the new source/drain 157 is located between two adjacent nanosheet columns. The new source/drain 157 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

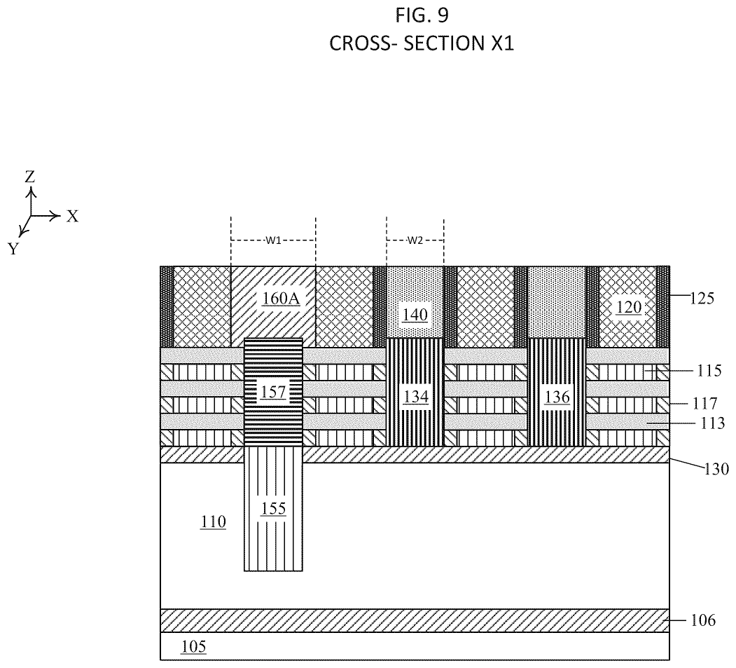

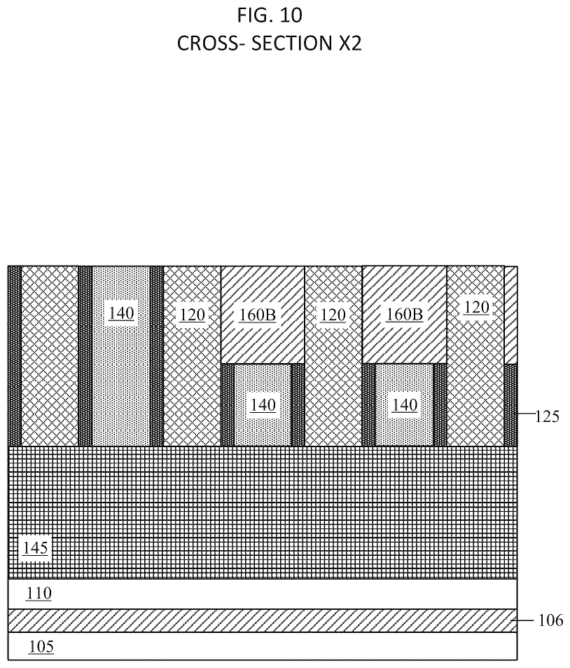

FIGS. 9 and 10 illustrate the processing stage after gate spacer 125 is pulled down, formation of a first dielectric cap 160A and a second dielectric cap 160B, and the removal of the hardmask 127. The gate spacer 125 located along the boundaries of the extended first trench 152A and along the boundaries of the extended second trench 152B is pulled down to expose the sidewalls of the dummy gate 120 of the gate regions that are located adjacent to the extended trenches 152A, 152B. A first dielectric cap 160A is formed on top of the new source/drain 157 and on top of a portion of the top channel layer 113 of the adjacent nanosheet columns. The bottom of surface of the first dielectric cap 160A is in contact with a frontside surface of the channel layer 113 and a frontside surface of the new source/drain 157. The sidewalls of the first dielectric cap 160A are each in contact with a sidewall of an adjacent dummy gate 120. The first dielectric cap 160A has a width W1 as measured along the X-axis (i.e., perpendicular to the gate direction). The width W1 of the first dielectric cap 160A is larger than the width of the source/drain region because of pull down/removal of some of the gate spacers 125. The removal/pull down of the gate spacers 125 allows for first dielectric cap 160 to be in contact with the new source/drain 157, the channel layer 113, and the dummy gate 120. The frontside interlayer dielectric layer 140 has a width W2 as measure along the X-axis, as illustrated in FIG. 9. The width W2 represents the width of the source/drain region where the frontside interlayer dielectric layer 140 is located. The width W1 of the first dielectric cap 160A is larger than the width W2 of the frontside interlayer dielectric layer 140.

FIG. 10 illustrates the second dielectric cap 160B being located in the region adjacent to the nanosheet transistor. The pull down of gate spacer 125 widens the extended second trench 152B and exposes a portion of the sidewalls of the dummy gate 120 located adjacent to the extended second trench 152B. The second dielectric cap 160B is formed on top of the frontside interlayer dielectric layer 140 and on top of the gate spacer 125, such that the bottom surface of the second dielectric cap 160B is in contact with a frontside surface of the frontside interlayer dielectric layer 140 and a frontside surface of the gate spacer 125. The sidewalls of the second dielectric cap 160B are each in contact with a sidewall of an adjacent dummy gate 120. The hardmask 127 is removed after the formation of the dielectric caps 160A, 160B.

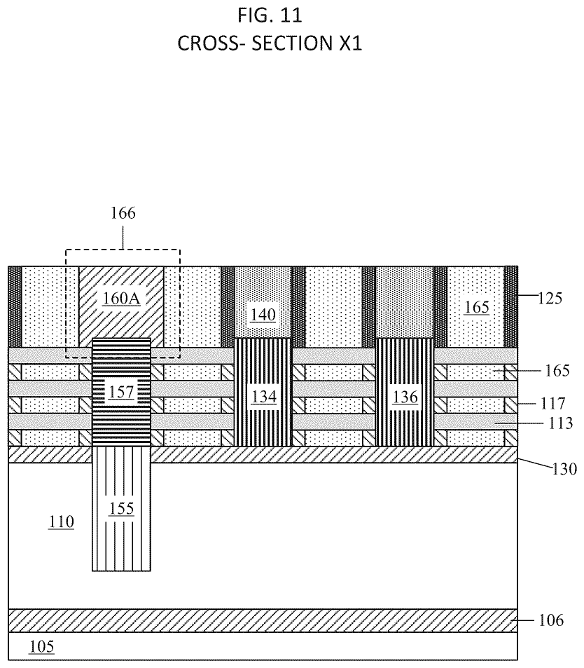

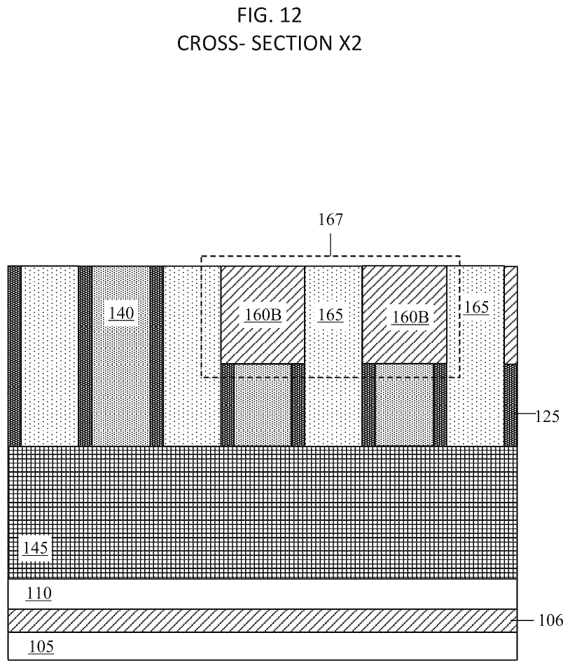

FIGS. 11 and 12 illustrate the processing stage after removal of the dummy gate 120 and the sacrificial layers 115 and the formation of the gate 165. The sacrificial layers 115 and the dummy gate 120 are selectively removed to create a void in the gate regions around channel layers 113 and adjacent to the gate spacer 125. Gate 165 is formed by filling in this void with the gate material. Gate 165 can be comprised of, for example, a gate dielectric liner, such as high-k dielectric like HfO₂, ZrO₂, HfLₐOₓ, etc., and work function layers, such as TIN, TiAIC, TiC, etc., and conductive metal fills, like W. The first dielectric cap 160A is in direct contact with the sidewalls of two adjacent gate 165 as emphasized by dashed box 166. Each of the second dielectric cap 160B is in direct contact with the sidewalls of two adjacent gate 165 as emphasized by dashed box 167. Dashed box 167 also emphasizes that gate 165 can be sandwiched between two second dielectric caps 160B, such that the sidewalls of the gate 165 are in contact with the sidewalls of two different second dielectric caps 160B.

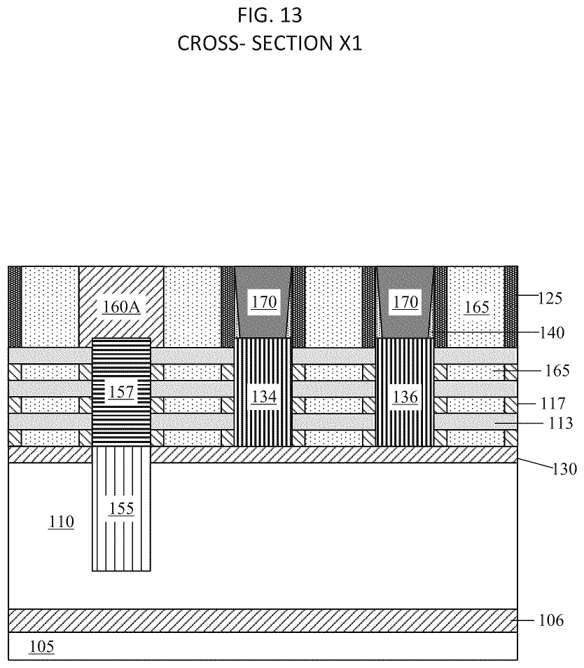

FIG. 13 illustrates the processing stage after formation of frontside source/drain contacts 170. Trenches (not shown) are formed in the frontside interlayer dielectric layer 140, where those trenches are located above source/drains 134, 136. These trenches (not shown) are filled in with a conductive material to form the frontside source/drain contacts 170. The bottom surface of the frontside source/drain contacts 170 is in contact with the frontside surface (i.e., the top surface) of the source/drain 134, 136, respectively. The top surface of the frontside source/drain contacts 170 is level with the top surface of the adjacent gates 165 and is level with a top surface of the first dielectric cap 160A. The frontside source/drain contacts 170 are located adjacent to gate spacer 125, such that gate spacer 125 is located between the frontside source/drain contacts 170 and the adjacent gates 165.

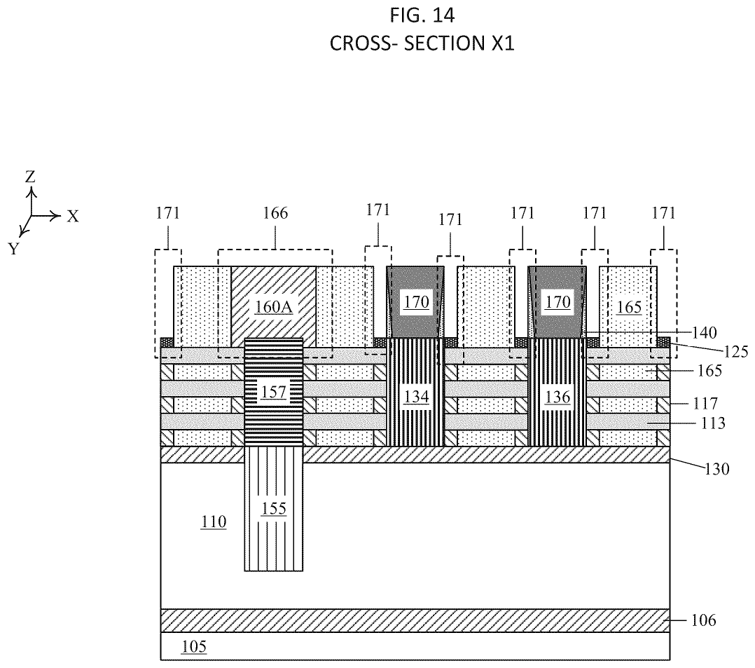

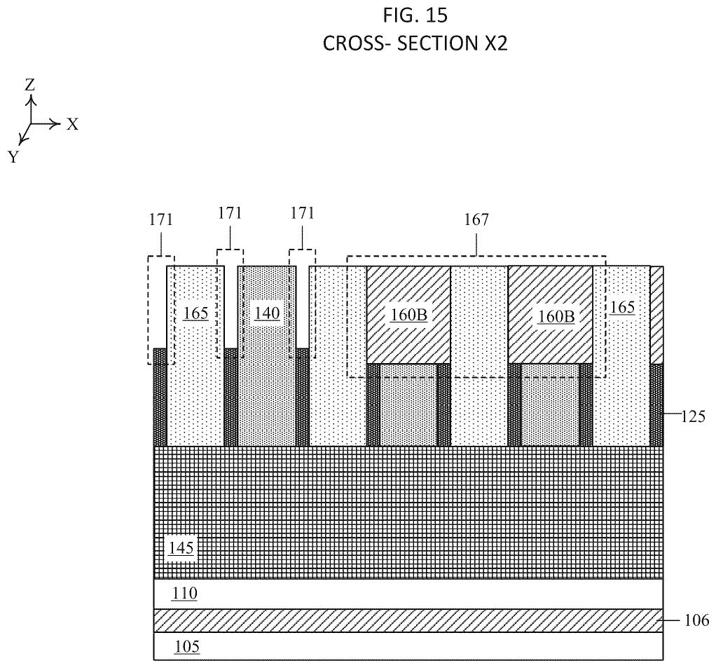

FIGS. 14 and 15 illustrate the processing stage after pulling down gate spacer 125 to create a plurality of trenches/valleys 171. Gate spacer 125 is pulled down/etched to create a plurality of trenches/valleys 171 located adjacent to each of the gates 165. A trench/valley is not created where the first and second dielectric caps 160A and 160B are located, as emphasized by dashed boxes 166, 167. The trench/valley 171 can be located between gate 165 and the frontside source/drain contact 170. Furthermore, trench/valley 171 can be located between gate 165 and the frontside interlayer dielectric layer 140, as illustrated in FIG. 15.

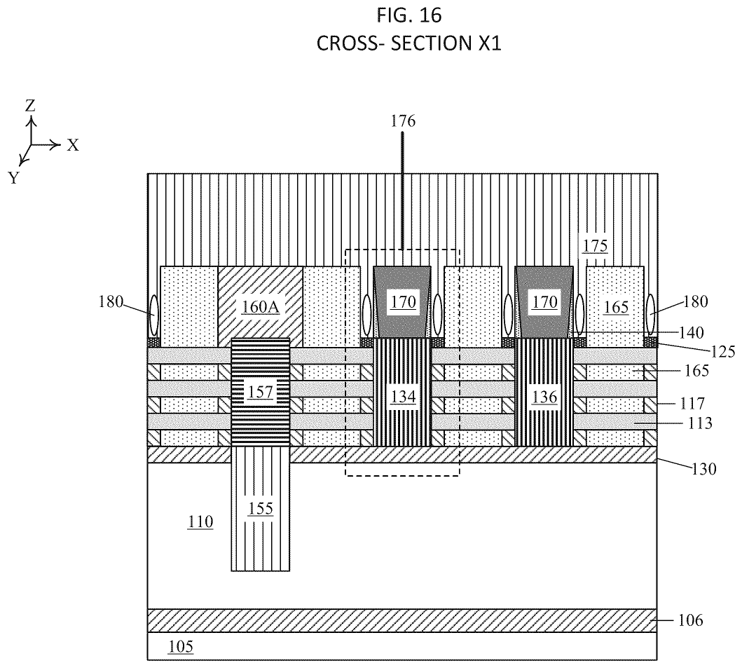

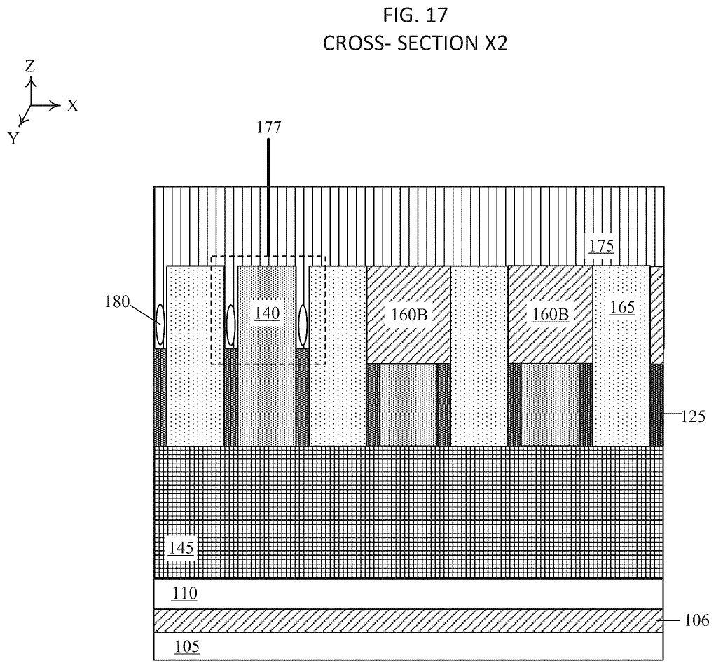

FIGS. 16 and 17 illustrate the processing stage after the non-conformal or conformal process (as long as it is not a liquid fill operation) for the formation of a dielectric layer 175. A dielectric layer 175 is formed on top of the nanosheet transistor, such that the dielectric layer 175 is formed by using a non-conformal process or a conformal process (as long as it is not a liquid fill operation), such as, for example, physical vapor deposition (PVD). The non-conformal or the conformal process (as long as it is not a liquid fill operation) deposition process used to form dielectric layer 175 causes the formation of airgaps 180. Airgaps 180 are formed because each of the trenches/valley 171 have a narrow width or a high aspect ratio, such that, the non-conformal deposition or the conformal deposition process (as long as it is not a liquid fill operation) causes the entrance/top opening of the trench/valley 171 to be pinched off/sealed prior to completely filling the trench/valley 171 with the dielectric material. Airgaps 180 reduces the parasitic capacitance between gate 165 and the adjacent frontside source/drain contacts 170. Each of the airgaps 180 is located between/sandwiched a sidewall of the frontside source/drain contact 170 and a sidewall of the adjacent gate 165, as emphasized by dashed box 176. The airgap 180 can vertically aligned with the inner spacer 117 such that the airgap 180 can be aligned over the end portions of channel layers 113, as emphasized by dashed box 176. Airgaps 180 can extend along the Y-axis (into the region adjacent to the nanosheet transistor) or the airgaps 180 can be located region adjacent to the nanosheet transistor without extending into the nanosheet transistor region. Portions of some of the airgaps 180 or independent airgaps 180 are located between a sidewall of the gate and a sidewall of the frontside interlayer dielectric layer 140, as emphasized by dashed box 177. The height of each of the airgaps 180 can vary from each other since height of the airgap 180 is dependent on when the trench/valley 171 is pinched off during the deposition process of the dielectric layer 175.

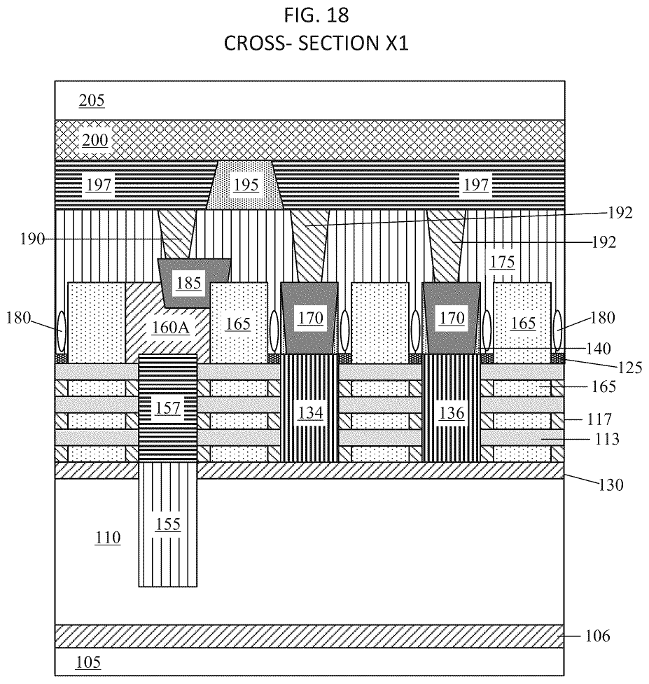

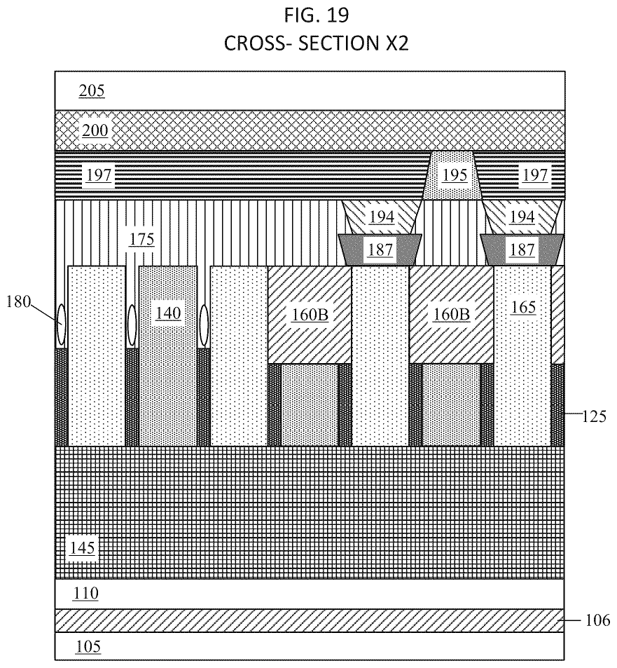

FIGS. 18 and 19 illustrate the processing stage after formation of gate contacts 185, 187, formation of connecting vias 190, 192, 194, formation for a second dielectric layer 195, formation of M1 metal lines 197, formation of back-end-of-the-lines (BEOL) layers 200, and formation of a carrier wafer 205. A plurality of trenches (not shown) are formed in the dielectric layer 175. These trenches are filled with a conductive material to form gate contacts 185, 187 and the connecting vias 190, 192, 194. The first dielectric cap 160A allows for the first gate contact 185 to be offset from the top surface of gate 165. The offset gate contact 185 is in contact with a top surface and a side surface of gate 165. The offsetting of the first gate contact 185 into the first dielectric cap 160A allows for misalignment errors and helps prevent shorting between the frontside source/drain contact 170 and the first gate contact 185. Furthermore, the top surface of the first gate contact 185 is higher than the top surface of the frontside source/drain contacts 170. The second gate contacts 187 are located on top of gate 165 in the region adjacent to the nanosheet transistor. The second dielectric caps 160B are located adjacent to the gates 165 in this region, thus allowing for misalignment/overlapping of the second gate contact 187 and the second dielectric cap 160B. Thus, the bottom surface of the second gate contacts 187 can be in direct contact with a top surface of the gate 165 and a top surface of the second dielectric cap 160B.

The first connecting vias 190 is connected to the first gate contact 185, the second connecting vias 192 are connected to the frontside source/drain contacts 170, and the third connecting vias 194 are connected to the second gate contacts 187. A second dielectric layer 195 is formed on top of the dielectric layer 175 and on top of the connecting vias 190, 192, 194. The second dielectric layer 195 is patterned to form a plurality of trenches (not shown). These trenches are filled with a connective metal to form a plurality of metal lines 197. The connecting vias 190, 192, 194 are connected to one of the plurality of metal lines 197. Each of the plurality of metal lines 197 can server a different purpose or the same purpose. For example, the metal lines 197 can be single lines, power lines (e.g., VSS or VDD), and or ground lines. Back-end-of-line (BEOL) layer 200 is formed on top of the plurality of metal lines 197 and on top of the second dielectric layer 195. Carrier wafer 205 is formed on top of the BEOL layer 200.

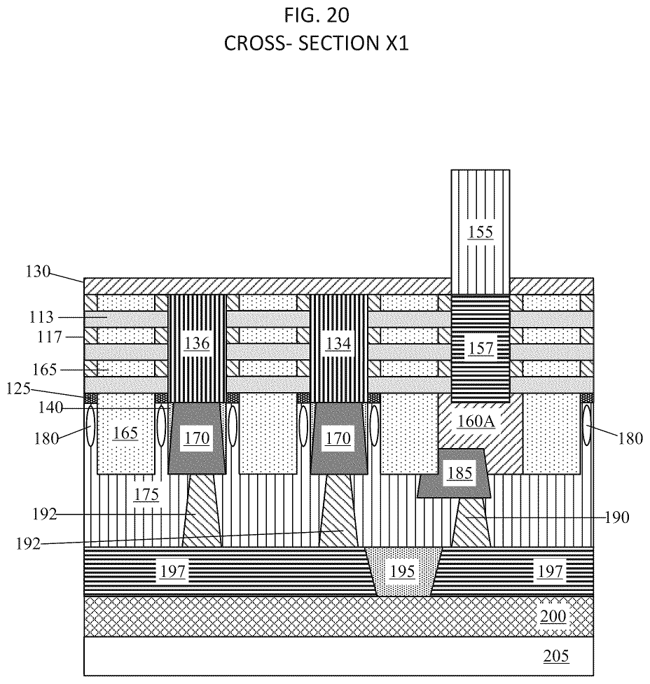

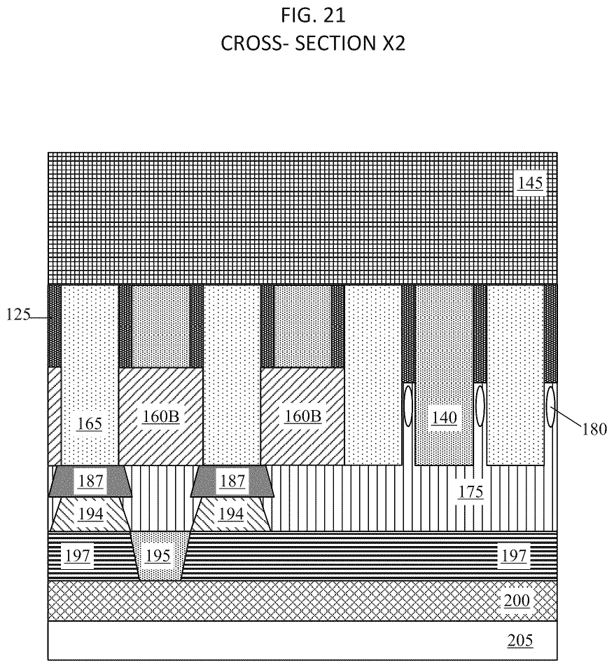

FIGS. 20 and 21 illustrate the processing stage after being flipped over for backside processing and the removal of the first substrate 105, the etch stop 106, the second substrate 110. Carrier wafer 205 allows for the wafer containing the nanosheet transistor to be flipped over for backside processing. FIGS. 20-24 illustrate the backside processing of the nanosheet transistor while FIG. 2-19 illustrated the frontside processing of the nanosheet transistor. The first substrate 105 is removed, then the etch stop 106 and the second substrate 110 are removed. The removal of these layers exposes the backside surface of the bottom dielectric isolation layer 130 and the shallow trench isolation layer 145. Placeholder 155 is exposed by the removal of these layers.

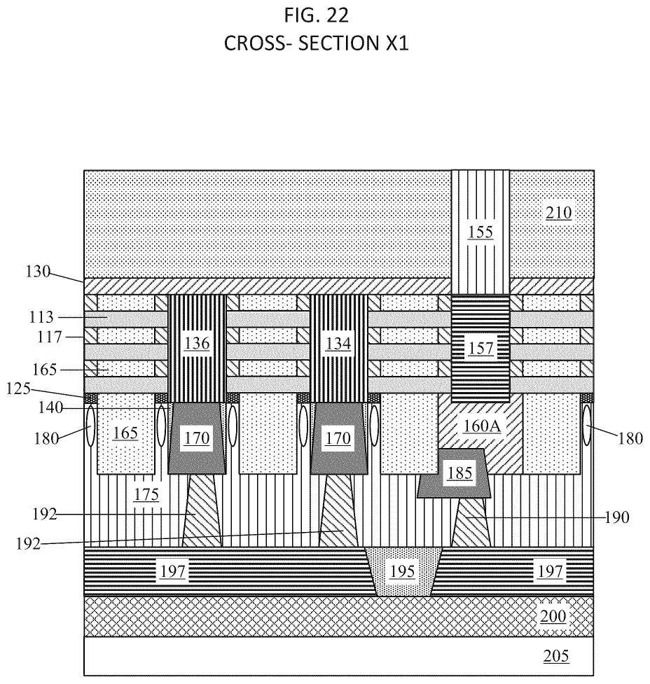

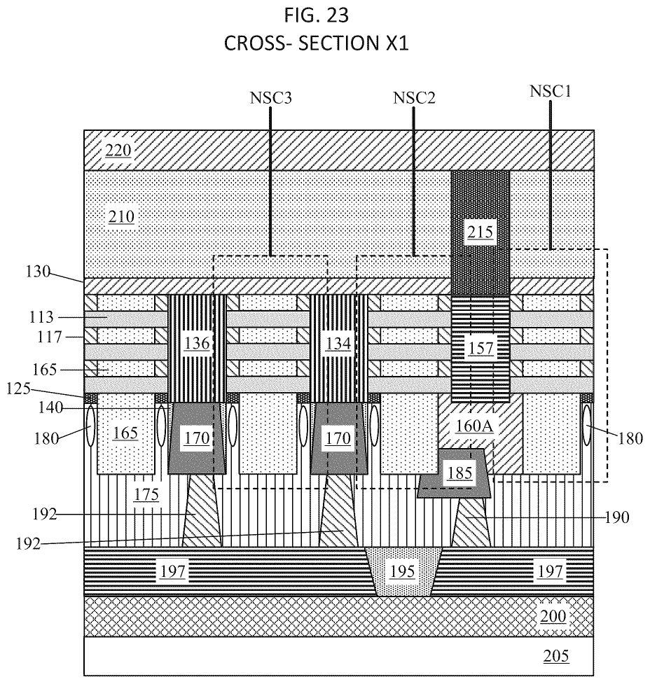

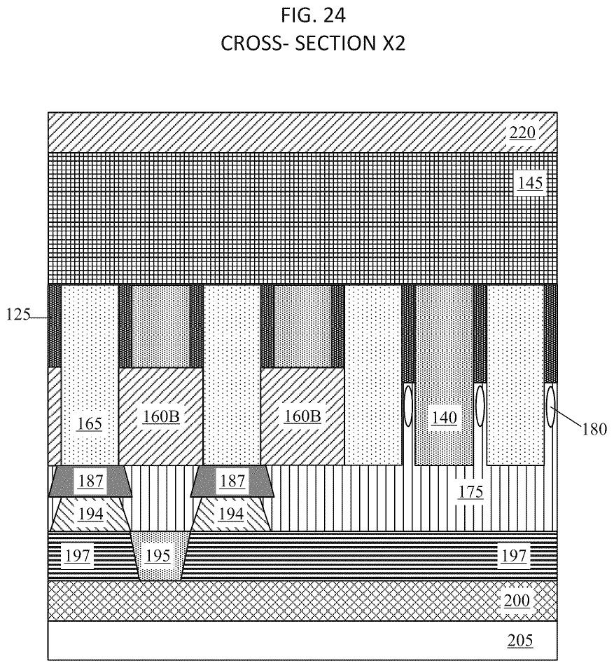

FIG. 22 illustrates the processing stage after formation of backside interlayer dielectric layer 210. A backside interlayer dielectric layer 210 is formed around the placeholder 155 and on top of the bottom dielectric isolation layer 130. FIGS. 23 and 24 illustrate the processing stage after removal of the placeholder 155, and the formation of the backside contact 215 and the backside-power-distribution-network (BSPDN) 220. The placeholder 155 is removed and metallization process is used to fill the void/space created by the removal of the placeholder 155 with a conductive material to form the backside contact 215. The backside contact 215 is in contact with the backside surface of the new source/drain 157. BSPDN 220 is formed on top of the backside interlayer dielectric layer 210, on top of the backside contact 215, and on top of the shallow trench isolation layer 145.

A microelectronic structure includes a first nanosheet transistor column NSC1. The first nanosheet transistor column NSC1 includes a plurality of first channel layers 113 and a first gate 165 located around each of the plurality of first channel layers 113. A second nanosheet transistor column NSC2 that includes a plurality of second channel layers 112 and a second gate 165 located around each of the plurality of second channel layers 113. The first nanosheet transistor column NSC1 is adjacent to the second nanosheet column NSC2. A source/drain 157 located between the first nanosheet transistor column NSC1 and the second nanosheet transistor column NSC2. A dielectric cap 160A located on top of and in direct contact with a frontside surface of the source/drain 157. The dielectric cap 160A is in contact with a sidewall of the first gate 165 and the dielectric cap 160A is in contact with a sidewall of the second gate 165.

The dielectric cap 160A extends laterally over the plurality of first channel layers 113 and the plurality of second channel layers 113. A bottom surface of the dielectric cap 160A is in contact with the source/drain 157, one of the plurality of first channel layers 113, and one of the plurality of second channel layers 113. A top surface of the dielectric cap 160A is level with a top surface of the first gate 165 and the top surface of the second gate 165.

A gate contact 185 is in direct contact to the second gate 165 of the second nanosheet transistor column NSC2. The gate contact 185 is in in direct contact with multiple surfaces of the second gate 165. The gate contact 185 is in contact with a side surface of the gate 165 and the top surface of the second gate 165. The gate contact 185 extends into the dielectric cap.

An airgap 180 located adjacent to the second gate 165, wherein the airgap 180 is located on the opposite side of the second gate 165 than the dielectric cap 160A. The airgap 180 and the dielectric cap 160A are located on the same level.

A microelectronic structure includes a first nanosheet transistor column NSC1. The first nanosheet transistor column NSC1 includes a plurality of first channel layers 113 and a first gate 165 located around each of the plurality of first channel layers 113. A second nanosheet transistor column NSC2 that includes a plurality of second channel layers 113 and a second gate 165 located around each of the plurality of second channel layers 113. The first nanosheet transistor column NSC1 is adjacent to the second nanosheet column NSC2. A first source/drain 157 located between the first nanosheet transistor column NSC1 and the second nanosheet transistor column NSC2. A dielectric cap 160A located on top of and in direct contact with a frontside surface of the first source/drain 157. The dielectric cap 160A is in contact with a sidewall of the first gate 165 and the dielectric cap 160A is in contact with a sidewall of the second gate 165. An airgap 180 located adjacent to the second gate 165. The airgap 180 is located on the opposite side of the second gate 165 than the dielectric cap 160A. The airgap 180 is vertically aligned over the plurality of second channel layers 113.

A third nanosheet transistor column NSC3 that includes a plurality of third channel layers 113 and a third gate 165 located around each of the plurality of third channel layers 113. The third nanosheet transistor column NSC3 is adjacent to the second nanosheet column NSC2. A second source/drain 134 located between the second nanosheet transistor column NSC2 and the third nanosheet transistor column NSC3.

A frontside contact 170 in direct contact with a frontside surface of the third source/drain 134. A dielectric layer 175 located on top of the first nanosheet transistor column NSC1, the second nanosheet transistor column NSC2, the third nanosheet transistor column NSC2, the dielectric cap 160A, and the frontside contact 170. The dielectric layer 175 is located between the second gate 165 and the frontside contact 170. The airgap 180 is located in the dielectric layer 175 between the second gate 165 and the frontside contact 170.

A microelectronic structure including a plurality of nanosheet transistor columns NSC1, NSC2, NSC3 and the plurality of nanosheet columns NSC1, NSC2, NSC3 are horizontally aligned. A first dielectric cap 160A located between and in contact with a gate 165 of two adjacent nanosheet transistor columns NSC1, NSC2 and the first dielectric cap 160A is horizontally aligned with the plurality of nanosheet columns NSC1, NSC2, NSC3. A second dielectric cap 160B located in a region adjacent to the plurality of nanosheet transistor columns NSC1, NSC2, NSC3 and the second dielectric cap 160B is located and in contact with two adjacent gates 165.

A bottom surface of the first dielectric cap 160A is in contact with a top surface of a source/drain 157. The bottom surface of the first dielectric cap 160A is in contact with a channel layer 113 of each of the two adjacent nanosheet columns NSC1, NSC2.

A first airgap 180 located adjacent to a gate 165 of one of the two adjacent nanosheet columns NSC2. The first airgap 180 is located on the opposite sides of the gate 165 than the first dielectric cap 160A.

A bottom surface of the second dielectric cap 160B is in contact with a top surface of a frontside interlayer dielectric layer 140. The bottom surface of the second dielectric cap 160B is in contact with a top surface of a first gate spacer 125 and a top surface of a second gate spacer 125. The first gate spacer 125 and second gate spacer 125 are located on opposite sides of the frontside interlayer dielectric layer 140.

A second airgap 180 located adjacent to a gate 165 of one of the two adjacent gates 165. The second airgap 180 is located on the opposite side of the gate 165 than the second dielectric cap 160B. The second airgap 180 is vertically aligned with third gate spacer 125.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first nanosheet transistor column, wherein the first nanosheet transistor column includes a plurality of first channel layers and a first gate located around each of the plurality of first channel layers;
a second nanosheet transistor column, wherein the second nanosheet transistor column includes a plurality of second channel layers and a second gate located around each of the plurality of second channel layers, wherein the first nanosheet transistor column is adjacent to the second nanosheet column;
a source/drain located between the first nanosheet transistor column and the second nanosheet transistor column; and
a dielectric cap located on top of and in direct contact with a frontside surface of the source/drain, wherein the dielectric cap is in contact with a sidewall of the first gate and the dielectric cap is in contact with a sidewall of the second gate.

2. The microelectronic structure of claim 1, wherein the dielectric cap extends laterally over the plurality of first channel layers and the plurality of second channel layers.

3. The microelectronic structure of claim 2, wherein a bottom surface of the dielectric cap is in contact with the source/drain, one of the plurality of first channel layers, and one of the plurality of second channel layers.

4. The microelectronic structure of claim 1, wherein a top surface of the dielectric cap is level with a top surface of the first gate and the top surface of the second gate.

5. The microelectronic structure of claim 4, further comprising:
a gate contact is in direct contact to the second gate of the second nanosheet transistor column, wherein the gate contact is in in direct contact with multiple surfaces of the second gate.

6. The microelectronic structure of claim 5, wherein the gate contact is in contact with a side surface of the second gate and the top surface of the second gate.

7. The microelectronic structure of claim 6, wherein the gate contact extends into the dielectric cap.

8. The microelectronic structure of claim 1, further comprising:
an airgap located adjacent to the second gate, wherein the airgap is located on the opposite side of the second gate than the dielectric cap.

9. The microelectronic structure of claim 8, wherein the airgap and the dielectric cap are located on the same level.

10. A microelectronic structure comprising:
a first nanosheet transistor column, wherein the first nanosheet transistor column includes a plurality of first channel layers and a first gate located around each of the plurality of first channel layers;
a second nanosheet transistor column, wherein the second nanosheet transistor column includes a plurality of second channel layers and a second gate located around each of the plurality of second channel layers, wherein the first nanosheet transistor column is adjacent to the second nanosheet column;
a first source/drain located between the first nanosheet transistor column and the second nanosheet transistor column;
a dielectric cap located on top of and in direct contact with a frontside surface of the first source/drain, wherein the dielectric cap is in contact with a sidewall of the first gate and the dielectric cap is in contact with a sidewall of the second gate; and
an airgap located adjacent to the second gate, wherein the airgap is located on the opposite side of the second gate than the dielectric cap, wherein the airgap is vertically aligned over the plurality of second channel layers.

11. The microelectronic structure of claim 10, further comprising:
a third nanosheet transistor column, wherein the third nanosheet transistor column includes a plurality of third channel layers and a third gate located around each of the plurality of third channel layers, wherein the third nanosheet transistor column is adjacent to the second nanosheet column; and
a second source/drain located between the second nanosheet transistor column and the third nanosheet transistor column.

12. The microelectronic structure of claim 11, further comprising:
a frontside contact in direct contact with a frontside surface of the third source/drain.

13. The microelectronic structure of claim 12, further comprising:
a dielectric layer located on top of the first nanosheet transistor column, the second nanosheet transistor column, the third nanosheet transistor column, the dielectric cap, and the frontside contact, wherein the dielectric layer is located between the second gate and the frontside contact.

14. The microelectronic structure of claim 13, wherein the airgap is located in the dielectric layer between the second gate and the frontside contact.

15. A microelectronic structure comprising:
a plurality of nanosheet transistor columns, wherein the plurality of nanosheet columns are horizontally aligned;
a first dielectric cap located between and in contact with a gate of two adjacent nanosheet transistor columns, wherein the first dielectric cap is horizontally aligned with the plurality of nanosheet columns; and
a second dielectric cap located in a region adjacent to the plurality of nanosheet transistor columns, wherein the second dielectric cap is located and in contact with two adjacent gates.

16. The microelectronic structure of claim 15, wherein a bottom surface of the first dielectric cap is in contact with a top surface of a source/drain, wherein the bottom surface of the first dielectric cap is in contact with a channel layer of each of the two adjacent nanosheet columns.

17. The microelectronic structure of claim 16, further comprising:
a first airgap located adjacent to a gate of one of the two adjacent nanosheet columns, wherein the first airgap is located on the opposite side of the gate than the first dielectric cap.

18. The microelectronic structure of claim 17, wherein a bottom surface of the second dielectric cap is in contact with a top surface of a frontside interlayer dielectric layer, wherein the bottom surface of the second dielectric cap is in contact with a top surface of a first gate spacer and a top surface of a second gate spacer, and wherein the first gate spacer and second gate spacer are located on opposite sides of the frontside interlayer dielectric layer.

19. The microelectronic structure of claim 18, further comprising:
a second airgap located adjacent to a gate of one of the two adjacent gates, wherein the second airgap is located on the opposite side of the gate than the second dielectric cap.

20. The microelectronic structure of claim 19, wherein the second airgap is vertically aligned with third gate spacer.
